(19) United States
(12) Patent Application Publication
(10) Pub. No.: US 2025/0176233 A1
(43) Pub. Date: May 29, 2025

(54) SEMICONDUCTOR DEVICE

(71) Applicant: MEDIATEK INC., Hsinchu City (TW)

(72) Inventors: Chih-Yang KAO, Hsinchu City (TW); Yuan-Fu CHUNG, Hsinchu City (TW); Tung-Hsing LEE, Hsinchu City (TW)

(21) Appl. No.: 18/948,774

(22) Filed: Nov. 15, 2024

Related U.S. Application Data
(63) Continuation-in-part of application No. 18/518,789, filed on Nov. 24, 2023.

(51) Int. Cl. H01L 29/06; H01L 27/06

(52) U.S. Cl. CPC H10D 62/124; H10D 84/811

(57) ABSTRACT

A semiconductor device is provided. The semiconductor device includes a semiconductor substrate, a gate structure and a first well region. The gate structure is disposed on the semiconductor substrate. The first well region having a first conductivity type is located in the semiconductor substrate. The first well region overlaps the gate structure. A first bottom of the first well region has a wave bottom surface.

### CROSS REFERENCE TO RELATED APPLICATIONS

This application is a Continuation-In-Part of pending U.S. patent application Ser. No. 18/518,789, filed Nov. 24, 2023 and entitled “ELECTROSTATIC DISCHARGE PROTECTION DEVICE”, the entirety of which is incorporated by reference herein.

### BACKGROUND OF THE DISCLOSURE

### Field of the Disclosure

The present disclosure relates to a semiconductor device, and, in particular, it relates to a well region of an HVMOS having tunable doping concentration.

### Description of the Related Art

Wireless communication systems are widely deployed to provide various telecommunication services such as telephony, video, data, messaging, and broadcasts. This will put pressure on semiconductor fabricators to develop RF chip modules for wireless transmission in different frequency ranges for transmission over short, medium and long distances. The RF power amplifier is an important component of the RF chip module located at the transmitter terminal. The main function of the RF power amplifier is to amplify the signal, after which the signal is transmitted through the antenna.

Although existing RF power amplifiers have generally been adequate for their intended purposes, they have not been satisfactory in all respects. For example, it is a challenge to balance the trade-off between cost and performance. Thus, a novel RF power amplifier formed by high voltage metal-oxide-semiconductor (HVMOS) devices is needed.

### BRIEF SUMMARY OF THE DISCLOSURE

An embodiment of the disclosure provides a semiconductor device. The semiconductor device includes a semiconductor substrate, a gate structure and a first well region. The gate structure is disposed on the semiconductor substrate. The first well region having a first conductivity type is located in the semiconductor substrate and overlaps the gate structure. A first bottom of the first well region has a wave bottom surface.

An embodiment of the disclosure provides a semiconductor device. The semiconductor device includes a semiconductor substrate, a gate structure and a first well region. The gate structure is disposed on the semiconductor substrate. The first well region having a first conductivity type is located in the semiconductor substrate and overlaps the gate structure. The first well region has a first number of first arc bottoms. The first number of first arc bottoms of the first well region is greater than or equal to 2.

### BRIEF DESCRIPTION OF THE DRAWINGS

The present disclosure can be more fully understood by reading the subsequent detailed description and examples with references made to the accompanying drawings, wherein:

FIG. 1 is a schematic cross-sectional view of a semiconductor device in accordance with some embodiments of the disclosure;

FIG. 2 is a schematic cross-sectional view of a semiconductor device in accordance with some embodiments of the disclosure;

FIG. 3 is a schematic cross-sectional view of a semiconductor device in accordance with some embodiments of the disclosure;

FIGS. 4A, 4B, 5A, 5B and 6 are schematic cross-sectional views at an intermediate stage of forming the semiconductor device of FIG. 1 in accordance with some embodiments of the disclosure;

FIGS. 7A, 7B, 8A, 8B and 9 are schematic cross-sectional views at an intermediate stage of forming the semiconductor device of FIG. 2 in accordance with some embodiments of the disclosure;

FIGS. 10A, 10B and 11 are schematic cross-sectional views at an intermediate stage of forming the semiconductor device of FIG. 3 in accordance with some embodiments of the disclosure; and

FIGS. 12A, 12B, 12C, 12D and 12E are plane views of first doped regions for forming the first well region of FIGS. 4A, 5A, 7A, 8A and 10A, showing the arrangements of discontinuous portions of the first doped regions of the semiconductor devices of FIGS. 1-3 in accordance with some embodiments of the disclosure.

### DETAILED DESCRIPTION OF THE DISCLOSURE

The following description is made for the purpose of illustrating the general principles of the disclosure and should not be taken in a limiting sense. The scope of the disclosure is best determined by reference to the appended claims.

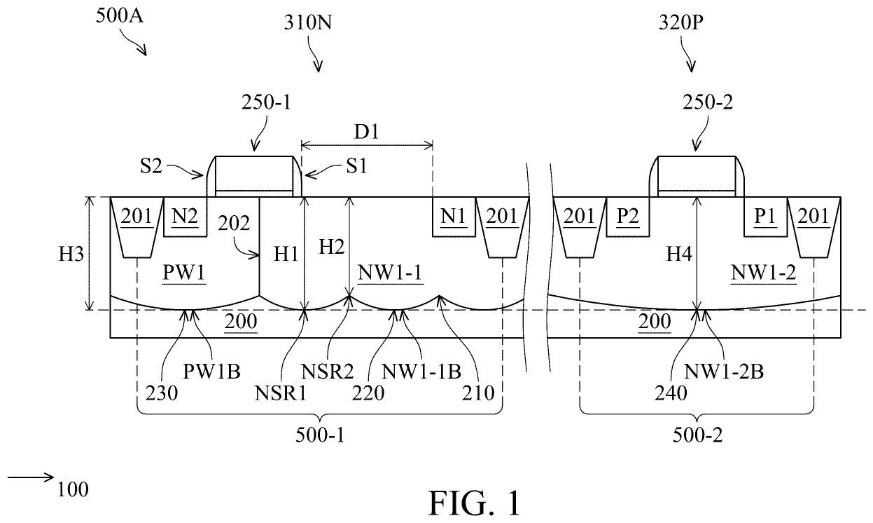

FIG. 1 is a schematic cross-sectional view of a semiconductor device 500A in accordance with some embodiments of the disclosure. The semiconductor device 500A may include transistors in different regions of a semiconductor substrate. For example, the semiconductor device 500A may include a high voltage N-type metal-oxide-semiconductor field effect transistor (HV NMOS FET) in a HV region and an input/output (I/O) P-type metal-oxide-semiconductor field effect transistor (PMOS FET) in a regular voltage region. In some embodiments, the HV NMOS FET includes a lateral diffused NMOS FET (LD NMOS FET).

In some embodiments, the semiconductor device 500A includes a semiconductor substrate 200, a transistor 310N and a transistor 320P.

In some embodiments, the semiconductor substrate 200 having a first device region 500-1 and a second device region 500-2 for elements (e.g., the transistors 310N and 320P) operated in different voltages disposed within. The semiconductor substrate 200 may include silicon. In alternative embodiments, SiGe, bulk semiconductor, strained semiconductor, compound semiconductor, semiconductor-on-insulator (SOI), and other commonly used semiconductor substrates can be used for the semiconductor substrate 200. In some embodiment, the semiconductor substrate 200 may have a conductivity type of P-type or N-type, depending on requirements. In some embodiments, the semiconductor substrate 200 may be P-type semiconductor substrate 200.

One or more isolation features 201, such as shallow trench isolation (STI) features or local oxidation of silicon (LOCOS) features, may be disposed in the semiconductor substrate 200. In addition, the isolation features 201 may surround and define active regions in the first device region 500-1 and the second device region 500-2. In some embodiment, the isolation features 201 are configured to provide physical and electrical isolation between the semiconductor device 500A and other semiconductor devices (not shown) in the semiconductor substrate 200.

The transistors 310N is disposed in the first device region 500-1 in the semiconductor substrate 200. In some embodiments, the transistor 310N may include a first well region NW1-1, a second well region PW1 and a gate structure 250-1.

The first well region NW1-1 and a second well region PW1 are located in the first device region 500-1 in the semiconductor substrate 200. The first well region NW1-1 and the second well region PW1 are arranged side-by-side along a direction 100 (the direction substantially parallel to a top surface 200T of the semiconductor substrate 200) and are adjacent to each other. The first well region NW1-1 and the second well region PW1 may extend from the top surface 200T of the semiconductor substrate 200 into a portion of the substrate 200 below the isolation features 201. In some embodiments, a first bottom NW1-1B of the first well region NW1-1 is connected to and in contact with a second bottom PW1B of the second well region PW1.

In some embodiments, the first well region NW1-1 has a first conductivity type, and the second well region PW1 has a second conductivity type that is opposite to the first has a first conductivity type. For example, when the first conductivity type is N-type and the second conductivity type is P-type, the first well regions NW1-1 is an N-type well region and the second well region PW1 is P-type well region. The first well region NW1-1 and the semiconductor substrate 200 may have the same or opposite conductivity types. In addition, the second well region PW1 and the semiconductor substrate 200 may have the same or opposite conductivity types.

In some embodiments, the first bottom NW1-1B of the first well region NW1-1 and the second bottom PW1B of the second well region PW1 have different profiles. For example, the first bottom NW1-1B of the first well region NW1-1 may have a wave surface, so that the first bottom NW1-1B may also be called a wavy bottom. The second bottom PW1B of the second well region PW1 may have an arc surface, so that the second bottom NW2B may also be called a rounded bottom (or an arc bottom). The first bottom NW1-1B of the first well region NW1-1 may have a wave profile as shown in FIG. 1. The second bottom PW1B of the second well region PW1 may have an arc profile as shown in FIG. 1. In some embodiments, a bottom surface of the first bottom NW1-1B of the first well region NW1-1 is also called a wave bottom surface, and a bottom surface of the second bottom PW1B of the second well region PW1 is also called an arc bottom surface. In some embodiments, the first well region NW1-1 has first sub-regions NSR1 and second sub-regions NSR2 alternately arranged with the first sub-regions NSR1. In some embodiments, there are 2 or more first sub-region NSR1, and there are 2 or more first sub-regions NSR1. The first sub-regions NSR1 may have a first depth H1. The second sub-regions NSR2 may have a second depth H2 that is different from the first depth H1. For example, the first sub-regions NSR1 may have convex bottoms, and the second sub-regions NSR2 may have concave bottoms. The convex bottoms of the first sub-regions NSR1 protrude in a direction away from the top surface 200T (or the top surface of the first well region NW1-1) of the semiconductor substrate 200. The concave bottoms of the second sub-regions NSR2 are recessed in a direction close to the top surface 200T (or the top surface of the first well region NW1-1) of the semiconductor substrate 200. In addition, the first depth H1 of the first sub-regions NSR1 having the convex bottoms may be deeper than the second depth H2 of the second sub-regions NSR2 having concave bottoms. In some embodiments, the first depth H1 is measured from the bottommost of the convex bottoms of the first sub-regions NSR1 to the top surface of the first well region NW1-1. In some embodiments, the second depth H2 is measured from the topmost of the concave bottoms of the second sub-regions NSR2 to the top surface of the first well region NW1-1. In some embodiments, as shown in FIG. 1, the wave profile of the first bottom NW1-1B (or the wave bottom surface of the first well region NW1-1) includes a plurality of wave crests 210 and a plurality of wave troughs 220, where the wave crests 210 are closer to the top surface of the first well region NW1-1 (or the top surface 200T of the semiconductor substrate 200) than the wave troughs 220. In some embodiments, the wave troughs 220 are the profile of the bottom of the first sub-regions NSR1, and the wave crests 210 are the profile of the bottom of the second sub-regions NSR2. In some embodiments, the wave troughs 220 are the bottom surface of the first sub-regions NSR1, and the wave crests 210 are the bottom surface of the second sub-regions NSR2. The first depth H1 is the distance measured from one of the wave troughs 220 (or the bottommost point of one of the wave troughs 220) to the top surface of the first well region NW1-1, while the second depth H2 is the distance measured from one of the wave crests 210 (or the topmost point of one of the wave crests 210) to the top surface of first well region NW1-1. In some embodiments, there are 2 or more wave crests 210 and two or more wave troughs 220. In some embodiments, the first well region NW1-1 has at least two points (the bottommost points) of the wave troughs 220, each with the first depth H1; and the first well region NW1-1 has at least two points (the topmost points) of the wave crests 210, each with the second depth H2. In some embodiments, the number of wave crests 210 and the number of wave troughs 220 in FIG. 1 are only for illustration, and are not limited thereto. In some embodiments, as shown in FIG. 1, the arc profile of the second bottom PW1B (or the arc bottom surface of the second well region PW1) only includes one wave trough 230, and the wave trough 230 protrudes in the direction away from the top surface 200T (or the top surface of the second well region PW1) of the semiconductor substrate 200. In some embodiments, the second bottom PW1B only includes one bottommost point of the wave trough 230, and a third depth H3 measured from the bottommost point to the top surface of the second well region PW1 may be equal to the first depth H1. In one embodiment, the top surface of the first well region NW1-1 is substantially flush with the top surface of the second well region PW1.

In some embodiments as shown in FIG. 1, the first well region NW1-1 and the second well region PW1 may have different number of arc bottoms. For example, the first well region NW1-1 may have a plurality of arc bottoms. The second well region PW1 may have a single arc bottom. Therefore, the number of arc bottoms of the first well region NW1-1 may be greater than the number of arc bottoms of the second well region PW1. In some embodiments, the end of one arc bottom may be connected to the adjacent end of another arc bottom. The arc bottom of the first well region NW1-1 adjacent to the second well region PW1 is connected to and in contact with the arc bottom of the second well region PW1. In some embodiments, the number of arc bottoms of the first well region NW1-1 may be greater than or equal to 2. In some embodiments, the plurality of arc bottoms is connected to each other in turn to form the wave bottom surface of the first well region NW1-1 (or the wave profile of the first bottom NW1-1B of the first well region NW1-1). In some embodiments, the first depth H1 measured from the bottommost point of one of the arc bottoms of the first well region NW1-1 to the top surface of the first well region NW1-1 is equal to the third depth H3 measured from the bottommost point of the single arc bottom of the second well region PW1 to the top surface of the second well region PW1. In one embodiment, the top surface of the first well region NW1-1 is substantially flush with the top surface of the second well region PW1.

The gate structure 250-1 is disposed on the top surface 200T of the semiconductor substrate 200 in the first device region 500-1. The gate structure 250-1 is formed over the first well region NW1-1 and the second well region PW1. In addition, the gate structure 250-1 may overlap the first well region NW1-1 and the second well region PW1. As shown in FIG. 1, the gate structure 250-1 may have opposite sides S1 and S2 located directly on the first well region NW1-1 and the second well region PW1, respectively. In some embodiments, an interface 202 between the first well region NW1-1 and the second well region PW1 may be located directly below the gate structure 250-1. In some embodiments, the gate structure 250-1 includes a gate dielectric layer, a gate electrode on the gate dielectric layer, and gate spacers on sidewalls of the gate dielectric layer and the gate electrode.

As shown in FIG. 1, the transistor 310N of the semiconductor device 500A further includes a first heavily doped region N1 and a second heavily doped region N2 respectively located on the first well region NW1-1 and the second well region PW1. The first heavily doped region N1 and the second heavily doped region N2 both have the first conductivity type. For example, when the first conductivity type is N-type, the first heavily doped region N1 is an N-type heavily doped region N1, and the second heavily doped region N2 is an N-type heavily doped region N2.

As shown in FIG. 1, the first heavily doped region N1 and the second heavily doped region N2 are located on the opposite sides S1 and S2 of the gate structure 250-1 and adjacent to the corresponding isolation features 201. In this embodiment, the first heavily doped region N1 and the second heavily doped region N2 are asymmetric to the gate structure 250-1. For example, in the direction 100, the side S1 of the gate structure 250-1 is separated from the first heavily doped region N1 by a distance D1, so that a portion of the first well region NW1-1 is exposed form the gate structure 250-1 and the first heavily doped region N1. In addition, the side S2 of the gate structure 250-1 is adjacent to the second heavily doped region N2.

In this embodiment, the gate structure 250-1, the first heavily doped region N1, the second heavily doped region N2 and the second well region PW1 of the semiconductor device 500A serve as the gate, the drain, the source and the bulk of the transistor 310N (e.g., a HV NMOS FET), respectively.

The transistor 320P is disposed in the second device region 500-2 in the semiconductor substrate 200. In some embodiments, the transistor 320P may include a third well region NW1-2, a gate structure 250-2, a third heavily doped region P1 and a fourth heavily doped region P2.

The third well region NW1-2 is located in the semiconductor substrate 200. In some embodiments, the first well region NW1-1 and the third well region NW1-2 both have the first conductivity type. For example, when the first conductivity type is N-type, the first and third well regions NW1-1, NW1-2 are N-type.

The third bottom NW1-2B of the third well region NW1-2 may have an arc surface. The third bottom NW1-2B of the third well region NW1-2 may have an arc profile as shown in FIG. 1. In some embodiments, a bottom surface of the third bottom NW1-2B of the third well region NW1-2 maybe called an arc bottom surface. In some embodiments, as shown in FIG. 1, the arc profile of the third bottom NW1-2B (or the arc bottom surface of the third well region NW1-2) only includes one wave trough 240, and the wave trough 240 protrudes in the direction away from the top surface 200T (or the top surface of the third well region NW1-2) of the semiconductor substrate 200. In some embodiments, the third bottom NW1-2B only includes one bottommost point of the wave trough 240, and a fourth depth H4 measured from the bottommost point to the top surface of the third well region NW1-2 may be equal to the first depth H1. In one embodiment, the top surface of the first well region NW1 is substantially flush with the top surface of the third well region NW1-2. As the first well region NW1 in the first device region 500-1 and the third well region NW1-2 in the second device region 500-2 are formed in the same process(es), the first depth H1 is equal to the fourth depth H4. The method of this embodiment can save manufacturing steps and costs (such as photomask costs) and improve manufacturing efficiency and manufacturing accuracy.

In some embodiments, the first well region NW1-1 having a wavy bottom (the first bottom NW1-1B) and the third well region NW1-2 having a rounded (or an arc) bottom (the third bottom NW1-2B) may have different doping concentrations. For example, the doping concentration of the first well region NW1-1 may be less than the doping concentration of the third well region NW1-2.

In some embodiments as shown in FIG. 1, the first well region NW1-1 and the third well region NW1-2 may have different number of arc bottoms. For example, the first well region NW1-1 may have a plurality of arc bottoms. The third well region NW1-2 may have a single arc bottom. Therefore, the number of arc bottoms of the first well region NW1-1 may be greater than the number of arc bottoms of the third well region NW1-2. And in one embodiment, the first well region NW1-1 and the third well region NW1-2 are formed in the same process rather than in different processes. Thus, this disclosure could save photomask costs and reduce process steps. In some embodiments, the end of one arc bottom may be connected to the adjacent end of another arc bottom. In some embodiments, the number of arc bottoms of the first well region NW1-1 may be greater than or equal to 2. In some embodiments, the plurality of arc bottoms is connected to each other in turn to form the wave bottom surface of the first well region NW1-1 (or the wave profile of the first bottom NW1-1B of the first well region NW1-1). In some embodiments, the first depth H1 measured from the bottommost point of one of the arc bottoms of the first well region NW1-1 to the top surface of the first well region NW1-1 is equal to the fourth depth H4 measured from the bottommost point of the single arc bottom of the third well region NW1-2 to the top surface of the third well region NW1-2. In one embodiment, the top surface of the first well region NW1-1 is substantially flush with the top surface of the third well region NW1-2. As the first well region NW1-1 and the third well region NW1-2 are formed in the same process(es), the first depth H1 is equal to the fourth depth H4. The method of this embodiment can save manufacturing steps and costs (such as photomask costs) and improve manufacturing efficiency and manufacturing accuracy.

The gate structure 250-2 is disposed on the top surface 200T of the semiconductor substrate 200 in the second device region 500-2. The gate structure 250-2 is formed over the third well region NW1-2. In addition, the gate structure 250-1 may overlap the third well region NW1-2. As shown in FIG. 1, opposite sides of the gate structure 250-2 are both located directly on the third well region NW1-2. In some embodiments, the gate structure 250-1 and the gate structure 250-2 include the same or similar structure and formed in the same process(es)

The third heavily doped region P1 and the fourth heavily doped region P2 are located on the third well region NW1-2. In some embodiments, the third heavily doped region P1 and the fourth heavily doped region P2 both have the second conductivity type. For example, when the first conductivity type is N-type and the second conductivity type is P-type, the third heavily doped region P1 is a P-type heavily doped region P1, and the fourth heavily doped region P2 is a P-type heavily doped region P2.

In this embodiment, the third heavily doped region P1 and the fourth heavily doped region P2 are asymmetric to the gate structure 250-2. For example, in the direction 100, the third heavily doped region P1 and the fourth heavily doped region P2 are adjacent to the opposite sides of the gate structure 250-2.

In this embodiment, the gate structure 250-2, the third heavily doped region P1, the fourth heavily doped region P2 and the semiconductor substrate 200 of the transistor 320P of the semiconductor device 500A serve as the gate, the drain, the source and the bulk of the transistor 320P (e.g., a regular PMOS FET or a core IO (input/output) PMOS FET), respectively. In some embodiments, transistor 320P has the opposite conductivity type as transistor 310N. The operation voltage of transistor 320P is lower than that of transistor 310N.

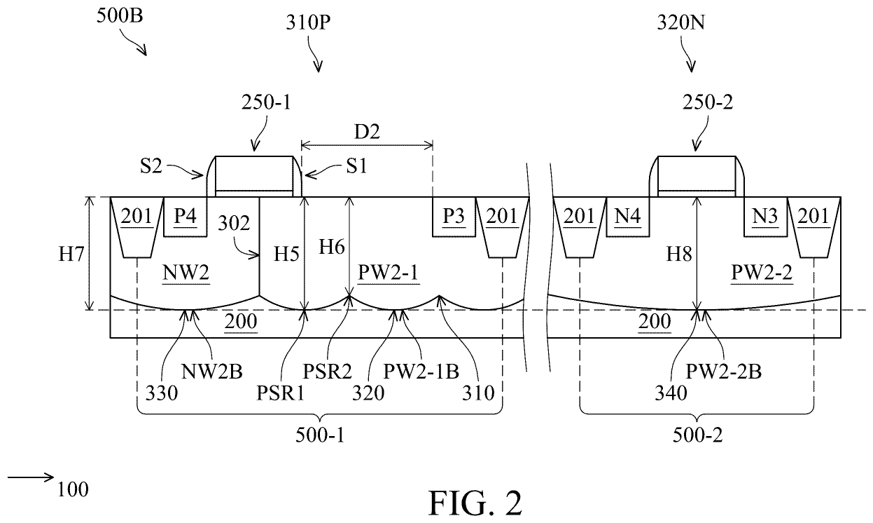

FIG. 2 is a schematic cross-sectional view of a semiconductor device 500B in accordance with some embodiments of the disclosure. Elements of the embodiments hereinafter, that are the same or similar as those previously described with reference to FIG. 1, are not repeated for brevity. As shown in FIGS. 1 to 2, the difference between the semiconductor device 500A and the semiconductor device 500B at least includes that the semiconductor device 500B has the opposite conductivity type as semiconductor device 500A. For example, in the semiconductor protection device 500A, the elements having the first conductivity type are N-type elements, and the elements having the second conductivity type are P-type elements. In the semiconductor protection device 500B, the elements having the first conductivity type are P-type elements, and the elements having the second conductivity type are N-type elements. The semiconductor device 500B may include transistors in different regions of a semiconductor substrate. For example, the semiconductor device 500B may include a high voltage P-type metal-oxide-semiconductor field effect transistor (HV PMOS FET) in a HV region and an input/output (I/O) N-type metal-oxide-semiconductor field effect transistor in a regular voltage (regular NMOS FET) region. In some embodiments, the HV PMOS FET includes a lateral diffused LD PMOS FET (LD PMOS FET).

As shown in FIG. 2, the semiconductor device 500B includes a semiconductor substrate 200, a transistor 310P and a transistor 320N.

The transistors 310P is disposed in the first device region 500-1 in the semiconductor substrate 200. In some embodiments, the transistor 310P may include a first well region PW2-1, a second well region NW2 and a gate structure 250-1.

In some embodiments, the first well region PW2-1 and the second well region NW2 are located in the semiconductor substrate 200. The first well region PW2-1 and the second well region NW2 are arranged side-by-side along the direction 100 (the direction substantially parallel to the top surface 200T of the semiconductor substrate 200) and are adjacent to each other. In some embodiments, a first bottom PW2-1B of the first well region PW2-1 is connected to and in contact with a second bottom NW2B of the second well region NW2.

In some embodiments, the first well region PW2-1 has the first conductivity type, and the second well region NW2 has the second conductivity type that is opposite to the first has a first conductivity type. For example, when the first conductivity type is P-type and the second conductivity type is N-type, the first well regions PW2-1 is a P-type well region and the second well region NW2 is N-type well region. The first well region PW2-1 and the semiconductor substrate 200 may have the same or opposite conductivity types. In addition, the second well region NW2 and the semiconductor substrate 200 may have the same or opposite conductivity types.

In some embodiments, the first well region PW2-1 of the semiconductor device 500B and the first well region NW1-1 of the semiconductor device 500A may have the same or similar profiles in the cross-sectional views, as shown in FIGS. 1 and 2. The second well region NW2 of the semiconductor device 500B and the second well region PW1 of the semiconductor device 500A may have the same or similar profiles in the cross-sectional views, as shown in FIGS. 1 and 2.

For example, the first bottom PW2-1B of the first well region PW2-1 may have a wave surface, so that the first bottom PW2-1B may also be called a wavy bottom. The second bottom NW2B of the second well region NW2 may have an arc surface, so that the second bottom NW2B may also be called a rounded bottom (or an arc bottom). The first bottom PW2-1B of the first well region PW2-1 may have a wave profile as shown in FIG. 2. The second bottom NW2B of the second well region NW2 may have an arc profile as shown in FIG. 2. In some embodiments, a bottom surface of the first bottom PW2-1B of the first well region PW2-1 is also called a wave bottom surface, and a bottom surface of the second bottom NW2B of the second well region NW2 is also called an arc bottom surface. In some embodiments, the first well region PW2-1 has first sub-regions PSR1 and second sub-regions PSR2 alternately arranged with the first sub-regions PSR1. In some embodiments, there are 2 or more first sub-regions PSR1 and there are 2 or more first sub-regions PSR1. The first sub-regions PSR1 may have a first depth H5. The second sub-regions PSR2 may have a second depth H6 that is different from the first depth H5. For example, the first sub-regions PSR1 may have convex bottoms, and the second sub-regions PSR2 may have concave bottoms. The convex bottoms of the first sub-regions PSR1 protrude in a direction away from the top surface 200T (or the top surface of the first well region PW2-1) of the semiconductor substrate 200. The concave bottoms of the second sub-regions PSR2 are recessed in a direction close to the top surface 200T (or the top surface of the first well region PW2-1) of the semiconductor substrate 200. In addition, the first depth H5 of the first sub-regions PSR1 having the convex bottoms may be deeper than the second depth H6 of the second sub-regions PSR2 having concave bottoms. In some embodiments, the first depth H5 is measured from the bottommost of the convex bottoms of the first sub-regions PSR1 to the top surface of the first well region PW2-1. In some embodiments, the second depth H6 is measured from the topmost of the concave bottoms of the second sub-regions PSR2 to the top surface of the first well region PW2-1. In some embodiments, as shown in FIG. 2, the wave profile of the first bottom PW2-1B (or the wave bottom surface of the first well region PW2-1) includes a plurality of wave crests 310 and a plurality of wave troughs 320, where the wave crests 310 are closer to the top surface of the first well region PW2-1 (or the top surface 200T of the semiconductor substrate 200) than the wave troughs 320. In some embodiments, the wave troughs 320 are the profile of the bottom of the first sub-regions PSR1, and the wave crests 310 are the profile of the bottom of the second sub-regions PSR2. In some embodiments, the wave troughs 320 are the bottom surface of the first sub-regions PSR1, and the wave crests 310 are the bottom surface of the second sub-regions PSR2. The first depth H5 is the distance measured from one of the wave troughs 320 (or the bottommost point of one of the wave troughs 320) to the top surface of the first well region PW2-1, while the second depth H6 is the distance measured from one of the wave crests 310 (or the topmost point of one of the wave crests 310) to the top surface of first well region PW2-1. In some embodiments, there are 2 or more wave crests 310 and there are 2 or more wave troughs 320. In some embodiments, the first well region PW2-1 has at least two points (the bottommost points) of the wave troughs 320, each with the first depth H5; and the first well region PW2-1 has at least two points (the topmost points) of the wave crests 310, each with the second depth H6. In some embodiments, the number of wave crests 310 and the number of wave troughs 320 in FIG. 2 are only for illustration, and are not limited thereto. In some embodiments, as shown in FIG. 2, the arc profile of the second bottom NW2B (or the arc bottom surface of the second well region NW2) only includes one wave trough 330, and the wave trough 330 protrudes in the direction away from the top surface 200T (or the top surface of the second well region NW2) of the semiconductor substrate 200. In some embodiments, the second bottom NW2B only includes one bottommost point of the wave trough 330, and a third depth H7 measured from the bottommost point to the top surface of the second well region NW2 may be equal to the first depth H5. In one embodiment, the top surface of the first well region PW2-1 is substantially flush with the top surface of the second well region NW2.

In some embodiments as shown in FIG. 2, the first well region PW2-1 and the second well region NW2 may have different number of arc bottoms. For example, the first well region PW2-1 may have a plurality of arc bottoms. The second well region NW2 may have a single arc bottom. Therefore, the number of arc bottoms of the first well region PW2-1 may be greater than the number of arc bottoms of the second well region NW2. In some embodiments, the end of one arc bottom may be connected to the adjacent end of another arc bottom. The arc bottom of the first well region PW2-1 adjacent to the second well region NW2 is connected to and in contact with the arc bottom of the second well region NW2. In some embodiments, the number of arc bottoms of the first well region PW2-1 may be greater than or equal to 2. In some embodiments, the plurality of arc bottoms is connected to each other in turn to form the wave bottom surface of the first well region PW2-1 (or the wave profile of the first bottom PW2-1B of the first well region PW2-1). In some embodiments, the first depth H5 measured from the bottommost point of one of the arc bottoms of the first well region PW2-1 to the top surface of the first well region PW2-1 is equal to the third depth H7 measured from the bottommost point of the single arc bottom of the second well region NW2 to the top surface of the second well region NW2. In one embodiment, the top surface of the first well region PW2-1 is substantially flush with the top surface of the second well region NW2.

The gate structure 250-1 is disposed on the top surface 200T of the semiconductor substrate 200 in the first device region 500-1. The gate structure 250-1 is formed over the first well region PW2-1 and the second well region NW2. In addition, the gate structure 250-1 may overlap the first well region PW2-1 and the second well region NW2. As shown in FIG. 2, the gate structure 250-1 may have opposite sides S1 and S2 located directly on the first well region PW2-1 and the second well region NW2, respectively. In some embodiments, an interface 302 between the first well region PW2-1 and the second well region NW2 may be located directly below the gate structure 250-1.

As shown in FIG. 2, the semiconductor device 500B further includes a first heavily doped region P3 and a second heavily doped region P4 respectively located on the first well region PW2-1 and the second well region NW2. The first heavily doped region P3 and the second heavily doped region P4 both have the first conductivity type. For example, when the first conductivity type is P-type, the first heavily doped region P3 is a P-type heavily doped region P3, and the second heavily doped region P4 is a P-type heavily doped region P4.

As shown in FIG. 2, the first heavily doped region P3 and the second heavily doped region P4 are located on the opposite sides S1 and S2 of the gate structure 250-1 and adjacent to the corresponding isolation features 201. In this embodiment, the first heavily doped region P3 and the second heavily doped region P4 are asymmetric to the gate structure 250-1. For example, in the direction 100, the side S1 of the gate structure 250-1 is separated from the first heavily doped region P3 by a distance D2, so that a portion of the first well region PW2-1 is exposed form the gate structure 250-1 and the first heavily doped region P3. In addition, the side S2 of the gate structure 250-1 is adjacent to the second heavily doped region P4.

In this embodiment, the gate structure 250-1, the first heavily doped region P3 and the second heavily doped region P4 and the semiconductor substrate 200 of the semiconductor device 500B serve as the gate, the drain, the source and the bulk of the transistor 310P (e.g., a HV PMOS FET), respectively.

The transistors 320N is disposed in the second device region 500-2 in the semiconductor substrate 200. In some embodiments, the transistor 320N may include a third well region PW2-2, a gate structure 250-2, a third heavily doped region N3 and a fourth heavily doped region N4.

The third well region PW2-2 is located in the semiconductor substrate 200. In some embodiments, the first well region PW2-1 and the third well region PW2-2 both have the first conductivity type. For example, when the first conductivity type is P-type, the first and third well regions PW2-1, PW2-2 are P-type.

The third bottom PW2-2B of the third well region PW2-2 may have an arc surface. The third bottom PW2-2B of the third well region PW2-2 may have an arc profile as shown in FIG. 2. In some embodiments, a bottom surface of the third bottom PW2-2B of the third well region PW2-2 maybe called an arc bottom surface. In some embodiments, as shown in FIG. 2, the arc profile of the third bottom PW2-2B (or the arc bottom surface of the third well region PW2-2) only includes one wave trough 340, and the wave trough 340 protrudes in the direction away from the top surface 200T (or the top surface of the third well region PW2-2) of the semiconductor substrate 200. In some embodiments, the third bottom PW2-2B only includes one bottommost point of the wave trough 340, and a fourth depth H8 measured from the bottommost point to the top surface of the third well region PW2-2 may be equal to the first depth H5. In one embodiment, the top surface of the first well region PW2-1 is substantially flush with the top surface of the third well region PW2-2. As the first well region PW2-1 in the first device region 500-1 and the third well region PW2-2 in the second device region 500-2 are formed in the same process(es), the first depth H5 is equal to the fourth depth H8. The method of this embodiment can save manufacturing steps and costs (such as photomask costs) and improve manufacturing efficiency and manufacturing accuracy.

In some embodiments, the first well region PW2-1 having a wavy bottom (the first bottom PW2-1B) and the third well region PW2-2 having a rounded (or an arc) bottom (the third bottom PW2-2B) may have different doping concentrations. For example, the doping concentration of the first well region PW2-1 may be less than the doping concentration of the third well region PW2-2.

In some embodiments as shown in FIG. 2, the first well region PW2-1 and the third well region PW2-2 may have different number of arc bottoms. For example, the first well region PW2-1 may have a plurality of arc bottoms. The third well region PW2-2 may have a single arc bottom. Therefore, the number of arc bottoms of the first well region PW2-1 may be greater than the number of arc bottoms of the third well region PW2-2. And in one embodiment, the first well region PW2-1 and the third well region PW2-2 are formed in the same process rather than in different processes. Thus, this disclosure could save photomask costs and reduce process steps. In some embodiments, the end of one arc bottom may be connected to the adjacent end of another arc bottom. In some embodiments, the number of arc bottoms of the first well region PW2-1 may be greater than or equal to 2. In some embodiments, the plurality of arc bottoms is connected to each other in turn to form the wave bottom surface of the first well region PW2-1 (or the wave profile of the first bottom PW2-1B of the first well region PW2-1). In some embodiments, the first depth H5 measured from the bottommost point of one of the arc bottoms of the first well region PW2-1 to the top surface of the first well region PW2-1 is equal to the fourth depth H8 measured from the bottommost point of the single arc bottom of the third well region PW2-2 to the top surface of the third well region PW2-2. In one embodiment, the top surface of the first well region PW2-1 is substantially flush with the top surface of the third well region PW2-2. As the first well region PW2-1 and the third well region PW2-2 are formed in the same process(es), the first depth H5 is equal to the fourth depth H8. The method of this embodiment can save manufacturing steps and costs (such as photomask costs) and improve manufacturing efficiency and manufacturing accuracy.

The gate structure 250-2 is disposed on the top surface 200T of the semiconductor substrate 200 in the second device region 500-2. The gate structure 250-2 is formed over the third well region PW2-2. In addition, the gate structure 250-1 may overlap the third well region PW2-2. As shown in FIG. 2, opposite sides of the gate structure 250-2 are both located directly on the third well region PW2-2. In some embodiments, the gate structure 250-1 and the gate structure 250-2 include the same or similar structure and formed in the same process(es)

The third heavily doped region N3 and the fourth heavily doped region N4 are located on the third well region PW2-2. In some embodiments, the third heavily doped region N3 and the fourth heavily doped region N4 both have the second conductivity type. For example, when the first conductivity type is P-type and the second conductivity type is N-type, the third heavily doped region N3 is a P-type heavily doped region P3, and the fourth heavily doped region N4 is a P-type heavily doped region P4.

In this embodiment, the third heavily doped region N3 and the fourth heavily doped region N4 are asymmetric to the gate structure 250-2. For example, in the direction 100, the third heavily doped region N3 and the fourth heavily doped region N4 are adjacent to the opposite sides of the gate structure 250-2.

In this embodiment, the gate structure 250-2, the third heavily doped region N3, the fourth heavily doped region N4 and the semiconductor substrate 200 of the transistor 320N of the semiconductor device 500B serve as the gate, the drain, the source and the bulk of the transistor 320N (e.g., a regular NMOS FET), respectively. In some embodiments, transistor 320N has the opposite conductivity type as transistor 310P. The operation voltage of the transistor 320N is lower than that of the transistor 310P.

The semiconductor devices 500A and 500B include transistors disposed in different regions having different operation voltages. For example, the first well region (e.g., the first well regions NW1-1, PW2-1) at the drain side of the HV transistor (e.g., the transistors 310N, 310P) in the HV region (e.g., the first device region 500-1) and the third well region (e.g., the third well regions NW1-2, PW2-2) of the I/O transistor (e.g., the transistors 320N, 320P) in the regular voltage region (e.g., the second device region 500-2) are formed simultaneously, but has different doping concentrations and different profiles. The performance of the HV transistor may be improved while the performance of the I/O device is maintained without additional masks and process steps.

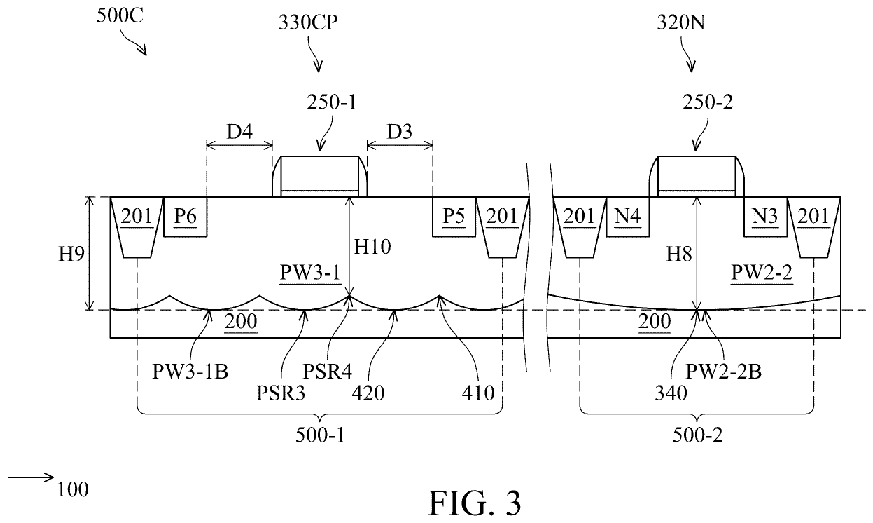

FIG. 3 is a schematic cross-sectional view of a semiconductor device 500C in accordance with some embodiments of the disclosure. Elements of the embodiments hereinafter, that are the same or similar as those previously described with reference to FIGS. 1 and 2, are not repeated for brevity. The semiconductor device 500C may include at least a capacitor and at least a transistor disposed in different regions of a semiconductor substrate. For example, the semiconductor device 500C may include a capacitor in a first device region and an input/output (I/O) N-type metal-oxide-semiconductor field effect transistor in a second device region.

As shown in FIG. 3, the semiconductor device 500C may include a semiconductor substrate 200, a capacitor 330CP and a transistor 320N.

The capacitor 330CP is disposed in the first device region 500-1 in the semiconductor substrate 200. In some embodiments, the capacitor 330CP may include a first well region PW3-1 and a gate structure 250-1.

As shown in FIG. 3, the first well region PW3-1 is located in the semiconductor substrate 200. The first well region PW3-1 may extend from the top surface 200T of the semiconductor substrate 200 into a portion of the substrate 200 below the isolation features 201.

In some embodiments, the first well region PW3-1 has a first conductivity type. For example, when the first conductivity type is P-type, the first well regions PW3-1 is a P-type well region. In addition, the first well region PW3-1 and the semiconductor substrate 200 may have the same or opposite conductivity types.

In some embodiments, the first bottom PW3-1B of the first well region PW3-1 may have a wave surface, so that the first bottom PW3-1B may also be called a wavy bottom. The first bottom PW3-1B of the first well region PW3-1 may have a wave profile as shown in FIG. 3. In some embodiments, a bottom surface of the first bottom PW3-1B of the first well region PW3-1 is also called a wave bottom surface. In some embodiments, the first well region PW3-1 has first sub-regions PSR3 and second sub-regions PSR4 alternately arranged with the first sub-regions PSR3. In some embodiments, there are 2 or more first sub-regions PSR3 and there are 2 or more second sub-regions PSR4. The first sub-regions PSR3 may have a first depth H9. The second sub-regions PSR4 may have a second depth H10 that is different from the first depth H9. For example, the first sub-regions PSR3 may have convex bottoms, and the second sub-regions PSR4 may have concave bottoms. The convex bottoms of the first sub-regions PSR3 protrude in a direction away from the top surface 200T (or the top surface of the first well region PW3-1) of the semiconductor substrate 200. The concave bottoms of the second sub-regions PSR4 are recessed in a direction close to the top surface 200T (or the top surface of the first well region PW3-1) of the semiconductor substrate 200. In addition, the first depth H9 of the first sub-regions PSR3 having the convex bottoms may be deeper than the second depth H10 of the second sub-regions PSR4 having concave bottoms. In some embodiments, the first depth H9 is measured from the bottommost of the convex bottoms of the first sub-regions PSR3 to the top surface of the first well region PW3-1. In some embodiments, the second depth H10 is measured from the topmost of the concave bottoms of the second sub-regions PSR4 to the top surface of the first well region PW3-1. In some embodiments, as shown in FIG. 3, the wave profile of the first bottom PW3-1B (or the wave bottom surface of the first well region PW3-1) includes a plurality of wave crests 410 and a plurality of wave troughs 420, where the wave crests 410 are closer to the top surface of the first well region PW3-1 (or the top surface 200T of the semiconductor substrate 200) than the wave troughs 420. In some embodiments, the wave troughs 420 are the profile of the bottom of the first sub-regions PSR3, and the wave crests 410 are the profile of the bottom of the second sub-regions PSR4. In some embodiments, the wave troughs 420 are the bottom surface of the first sub-regions PSR3, and the wave crests 410 are the bottom surface of the second sub-regions PSR4. The first depth H9 is the distance measured from one of the wave troughs 420 (or the bottommost point of one of the wave troughs 420) to the top surface of the first well region PW3-1, while the second depth H10 is the distance measured from one of the wave crests 410 (or the topmost point of one of the wave crests 410) to the top surface of first well region PW3-1. In some embodiments, there are 2 or more wave crests 410 and there are 2 or more wave troughs 420. In some embodiments, the first well region PW3-1 has at least two points (the bottommost points) of the wave troughs 420, each with the first depth H9; and the first well region PW3-1 has at least two points (the topmost points) of the wave crests 410, each with the second depth H10. In some embodiments, the number of wave crests 410 and the number of wave troughs 420 in FIG. 3 are only for illustration, and are not limited thereto.

In some embodiments as shown in FIG. 3, the first well region PW3-1 may have a plurality of arc bottoms. In some embodiments, the first well region PW3-1 may have 2 or more arc bottoms. In some embodiments, the arc bottoms are connected to each other in turn to form the wave bottom surface of the first well region PW3-1 (or the wave profile of the first bottom PW3-1B of the first well region PW3-1).

The gate structure 250-1 is disposed on the top surface 200T of the semiconductor substrate 200 in the first device region 500-1. The gate structure 250-1 is formed over the first well region PW3-1. In addition, the gate structure 250-1 may overlap the first well region PW3-1. As shown in FIG. 3, the gate structure 250-1 may have opposite sides S1 and S2 both located directly on the first well region PW3-1.

As shown in FIG. 3, the semiconductor device 500C further includes a first heavily doped region P5 and a second heavily doped region P6 located on the first well region PW3-1. The first heavily doped region P5 and the second heavily doped region P6 both have the first conductivity type. For example, when the first conductivity type is P-type, the first heavily doped region P5 is a P-type heavily doped region P5, and the second heavily doped region P6 is a P-type heavily doped region P6.

As shown in FIG. 3, the first heavily doped region P5 and the second heavily doped region P6 are located on opposite sides S1 and S2 of the gate structure 250-1 and adjacent to the corresponding isolation features 201. In this embodiment, the first heavily doped region P5 and the second heavily doped region P6 are symmetric to the gate structure 250-1. For example, in the direction 100, the side S1 of the gate structure 250-1 is separated from the first heavily doped region P5 by a distance D3, so that a portion of the first well region PW3-1 is exposed form the gate structure 250-1 and the first heavily doped region P5. In addition, in the direction 100, the side S2 of the gate structure 250-1 is separated from the second heavily doped region P6 by a distance D4, so that another portion of the first well region PW3-1 is exposed form the gate structure 250-1 and the second heavily doped region P6. In some embodiments, the distance D3 is equal to the distance D4.

In this embodiment, the first heavily doped region P5 is electrically connected (or coupled) to the second heavily doped region P6. The gate structure 250-1 may serve as the first electrode of the capacitor 330CP. In addition, the first heavily doped region P5 and the second heavily doped region P6 may collectively serve as the second electrode of the capacitor 330CP.

The transistors 320N is disposed in the second device region 500-2 in the semiconductor substrate 200. In some embodiments, the transistors 320N of the semiconductor devices 500A and 500C may have the same or similar structure. In some embodiments, the first well region PW3-1 in the first device region 500-1 and the third well region PW2-2 in the second device region 500-2 are formed in the same process(es), the first depth H9 is equal to the fourth depth H8. The method of this embodiment can save manufacturing steps and costs (such as photomask costs) and improve manufacturing efficiency and manufacturing accuracy.

Methods for forming the semiconductor devices 500A, 500B and 500C are described below.

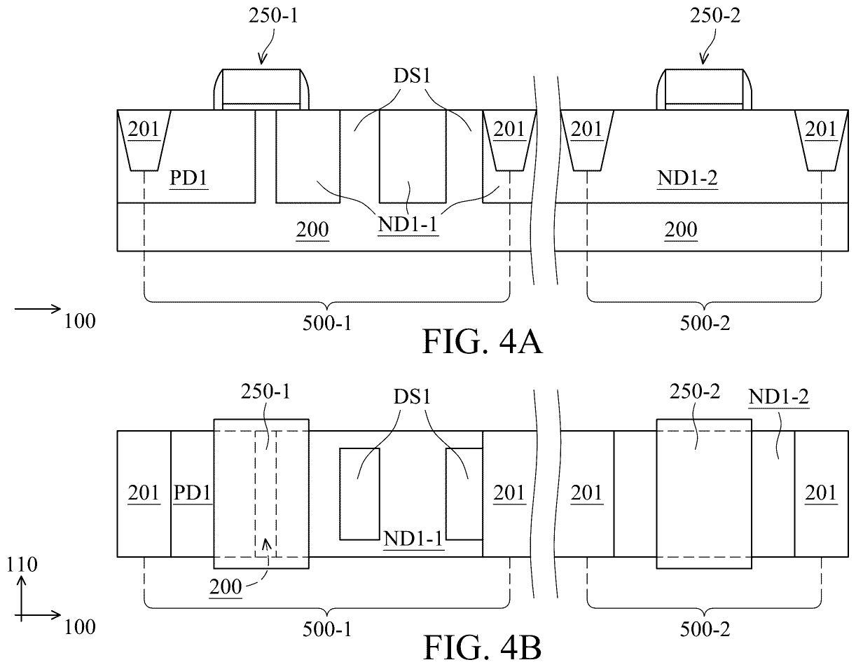

FIGS. 4A, 4B, 5A, 5B and 6 are schematic cross-sectional views at an intermediate stage of forming the semiconductor device 500A of FIG. 1 in accordance with some embodiments of the disclosure.

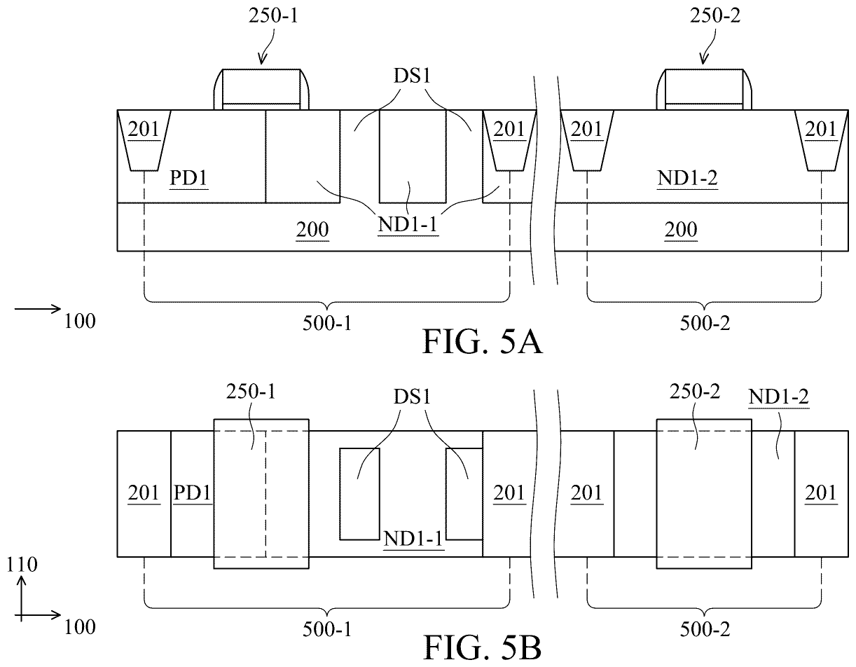

Referring to FIGS. 4A, 4B, 5A and 5B, the semiconductor substrate 200 is provided. The semiconductor substrate 200 has a first device region 500-1 and a second device region 500-2 separated from the first device region 500-1 by the isolation feature 201. The first device region 500-1 may provide a transistor 310N formed therein, and the second device region 500-2 may provide a transistor 320P formed therein.

Next, several implantation processes are performed to form a first doped region ND1-1 and a second doped region PD1 and a third doped region ND1-2 in the semiconductor substrate 200. The first doped region ND1-1 and the second doped region PD1 are individually formed in the same first device region 500-1 of the semiconductor substrate 200. In addition, the first doped region ND1-1 and the third doped region ND1-2 are simultaneously formed in the first device region 500-1 and the whole second device region 500-2. The first doped region ND1-1 and the second doped region PD1 are close to each other. In some embodiments, the first doped region ND1-1 may be separated from the second doped region PD1, as shown in FIGS. 4A and 4B. Alternatively, the first doped region ND1-1 may be connected to (or in contact with) the second doped region PD1, as shown in FIGS. 5A and 5B.

In some embodiments, the first doped region ND1-1 has at least one discontinuous portion DS1 within. The conductivity type, composition or doping concentration of the discontinuous portion DS1 may be different from the first doped region ND1-1, but the same as that of the semiconductor substrate 200. The second doped region PD1 and the third doped region ND1-2 may be formed without discontinuous portions within. In some embodiments, the second doped region PD1 and the third doped region ND1-2 are continuous doped regions. There are no other portions within the second doped region PD1 that have a different conductivity type, composition or doping concentration of the second doped region PD1. Similarly, there are no other portions within the third doped region ND1-2 that have a different conductivity type, composition or doping concentration of the third doped region ND1-2. In some embodiments, the implantation processes are different ion implantation processes and implanted with dopants of different conductivity types. For example, the first doped region ND1-1 and the third doped region ND1-2 may have the first conductivity type by implanting an N-type dopant, which may include phosphorus, arsenic, nitrogen, antimony, or a combination thereof. For example, the second doped region PD1 may have the second conductivity type (i.e., P-type) by implanting a P-type dopant, which may include boron, gallium, aluminum, indium, boron trifluoride ions (BF₃⁺), or a combination thereof.

Next, still referring to FIGS. 4A, 4B, 5A and 5B, deposition processes, patterning processes and etching back processes are performed to simultaneously form gate structures 250-1 and 250-2 on the semiconductor substrate 200 in the first device region 500-1 and the second device region 500-2. The gate structure 250-1 may overlap both the first doped region ND1-1 and the second doped region PD1. The gate structure 250-2 may overlap the third doped region ND1-2.

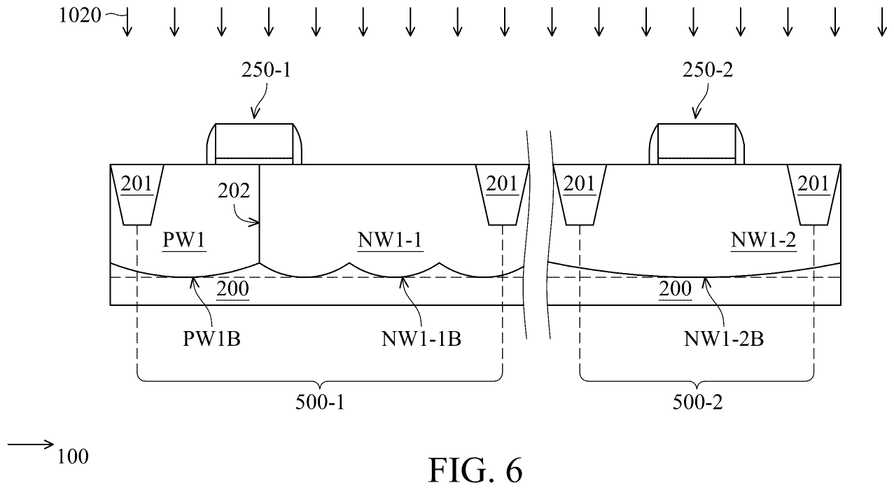

Next, referring to FIG. 6, an annealing process 1020 is performed to form a first well region NW1-1 from the first doped region ND1-1 (FIGS. 4A, 4B, 5A and 5B), a second well region PW1 from the second doped region PD1 (FIGS. 4A, 4B, 5A and 5B) and a third well region NW1-2 from the third doped region ND1-2 (FIGS. 4A, 4B, 5A and 5B). In some embodiments, the first well region NW1-1 is formed by diffusing a portion of dopants (e.g., N-type dopants) in the first doped region ND1-1 into the discontinuous portion DS1 (FIGS. 4A, 4B, 5A and 5B). Therefore, the first well region NW1-1 and the adjacent second well region PW1 (or the third well region NW1-2) may have different bottom profiles and doping concentrations. For example, the first well region NW1-1 may have the wavy bottom (the first bottom NW1-1B) and the second well region PW1 (or the third well region NW1-2) may have the arc (or rounded) bottom (e.g., the second bottom PW1B or the third bottom NW1-2B).

In some embodiments, the doping concentration of the first well region NW1-1 may be less than the doping concentration of the third well region NW1-2. In some embodiments, as the first well region NW1-1 in the first device region 500-1 and the third well region NW1-2 in the second device region 500-2 having different doping concentrations are simultaneously formed without additional masks and process steps.

Compared with the conventional well region formed from the continuous doped region, the doping concentration of the first well region NW1-1 formed from the discontinuous doped region ND1-1 may have lower doping concentration. Furthermore, the doping concentration of the first well region NW1-1 is adjustable by the number and size of the discontinuous portion DS1. In some embodiments, as the first well region NW1-1 having tunable doping concentrations is formed without additional masks and process steps. The method of this embodiment can save manufacturing steps and costs (such as photomask costs) and improve manufacturing efficiency and manufacturing accuracy.

Next, referring to FIG. 1, a photolithography process and a subsequent implantation process may be performed to form the first heavily doped region N1 and the second heavily doped region N2. The first heavily doped region N1 having the first conductivity type (e.g., N-type) is located on the first well region NW1-1. The second heavily doped region N2 having the first conductivity type (e.g., N-type) is located on the second well region NW2. In some embodiments, the first heavily doped region N1 and the second heavily doped region N2 are arranged adjacent to the corresponding isolation features 201.

Next, referring to FIG. 1, another photolithography process and a subsequent implantation process may be performed to form the third heavily doped region P1 and the fourth heavily doped region P2. The third heavily doped region P1 and the fourth heavily doped region P2 having the second conductivity type (e.g., P-type) are both located on the third well region NW1-2. In some embodiments, the sequences of the processes of forming the first and the second heavily doped regions N1, N2 and the third and fourth heavily doped regions P1, P2 can be exchanged. After the aforementioned processes, the semiconductor device 500A is formed.

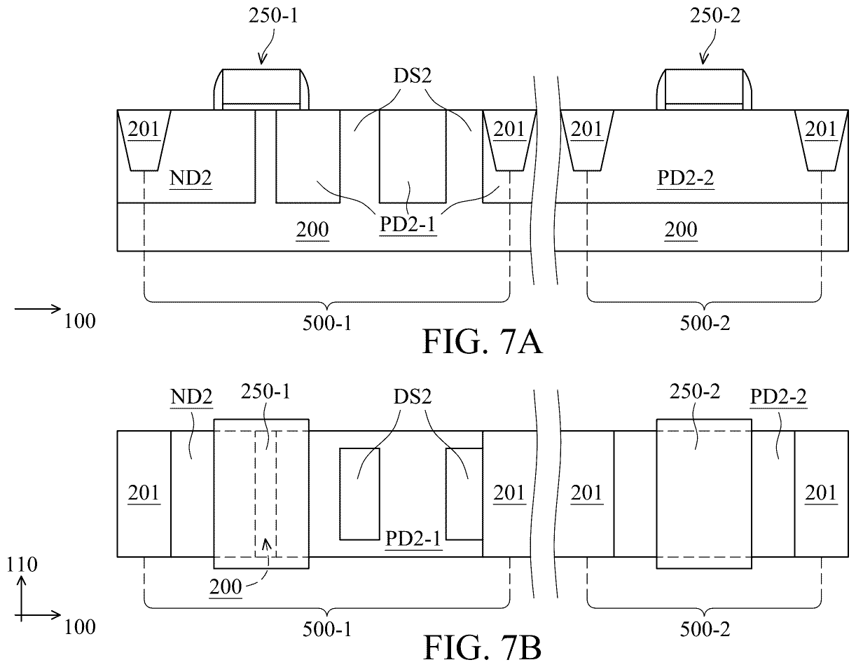

FIGS. 7A, 7B, 8A, 8B and 9 are schematic cross-sectional views at an intermediate stage of forming the semiconductor device 500B of FIG. 2 in accordance with some embodiments of the disclosure. Elements of the embodiments hereinafter, that are the same or similar as those previously described with reference to FIGS. 4A, 4B, 5A, 5B and 6, are not repeated for brevity.

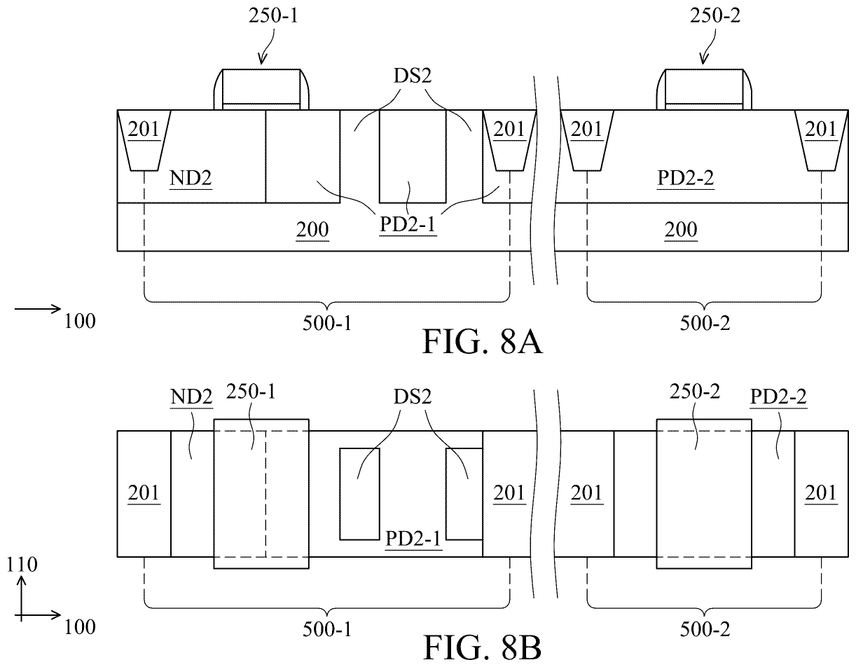

Referring to FIGS. 7A, 7B, 8A and 8B, several implantation processes are performed to individually form a first doped region PD2-1 and a second doped region ND2 and a third doped region PD2-2 in the semiconductor substrate 200. The first doped region PD2-1 and the second doped region ND2 are individually formed in the same first device region 500-1 of the semiconductor substrate 200. In addition, the first doped region PD2-1 and the third doped region PD2-2 are simultaneously formed in the first device region 500-1 and the whole second device region 500-2. The first doped regions PD2-1 and ND1-1 (FIGS. 4A, 4B, 5A and 5B) may have similar arrangements, but have opposite conductivity types. The second doped regions ND2 and PD1 (FIGS. 4A, 4B, 5A and 5B) may have similar arrangements, but have opposite conductivity types. The third doped regions PD2-2 and ND1-2 (FIGS. 4A, 4B, 5A and 5B) may have similar arrangements, but have opposite conductivity types.

In some embodiments, the first doped region PD2-1 has at least one discontinuous portion DS2 within. The second doped region ND2 and the third doped region PD2-2 may be formed without discontinuous portions within. In some embodiments, the implantation processes are different ion implantation processes and implanted with dopants of different conductivity types. For example, the first doped region PD2-1 may have the first conductivity type (i.e., P-type) by implanting a P-type dopant, which may include boron, gallium, aluminum, indium, boron trifluoride ions (BF₃⁺), or a combination thereof. For example, the second doped region ND2 may have the second conductivity type (i.e., N-type) by implanting an N-type dopant, which may include phosphorus, arsenic, nitrogen, antimony, or a combination thereof.

Next, still referring to FIGS. 7A, 7B, 8A and 8B, the processes similar to those shown in FIGS. 4A, 4B, 5A and 5B are performed to simultaneously form the gate structures 250-1 and 250-2 on the semiconductor substrate 200 in the first device region 500-1 and the second device region 500-2. The gate structure 250-1 may overlap both the first doped region PD2-1 and the second doped region ND2. The gate structure 250-2 may overlap the third doped region PD2-2.

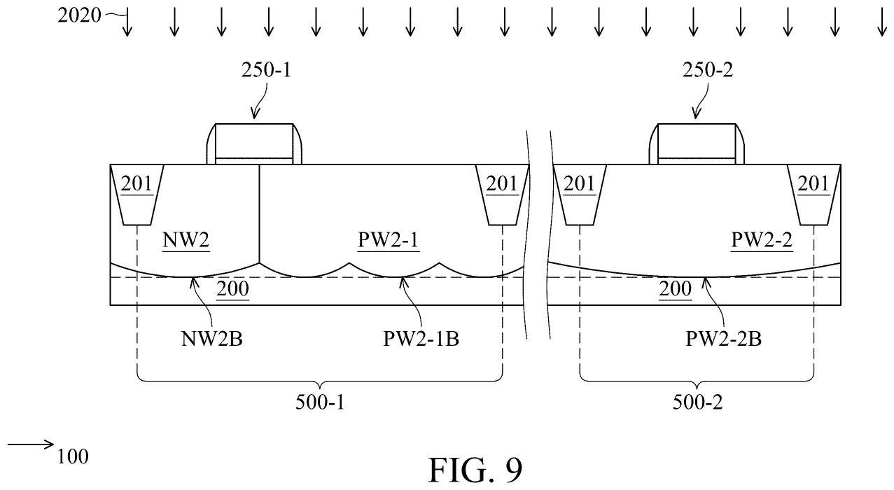

Next, referring to FIG. 9, an annealing process 2020 similar to the annealing process 1020 (FIG. 6) is performed to form a first well region PW2-1 from the first doped region PD2-1 (FIGS. 7A, 7B, 8A and 8B), a second well region NW2 from the second doped region ND2 (FIGS. 7A, 7B, 8A and 8B) and a third well region PW2-2 from the third doped region PD2-2 (FIGS. 7A, 7B, 8A and 8B). In some embodiments, the first well region PW2-1 is formed by diffusing a portion of dopants (e.g., P-type dopants) in the first doped region PD2-1 into the discontinuous portion DS2 (FIGS. 7A, 7B, 8A and 8B). Therefore, the first well region PW2-1 and the adjacent second well region NW2 (or the third well region PW2-2) may have different bottom profiles and doping concentrations. For example, the first well region PW2-1 may have the wavy bottom (the first bottom PW2-1B) and the second well region NW2 (or the third well region PW2-2) may have the arc (or rounded) bottom (e.g., the second bottom NW2B or the third bottom PW2-2B).

In some embodiments, the doping concentration of the first well region PW2-1 may be less than the doping concentration of the third well region PW2-2. In some embodiments, as the first well region PW2-1 in the first device region 500-1 and the third well region PW2-2 in the second device region 500-2 having different doping concentrations are simultaneously formed without additional masks and process steps.

Compared with the conventional well region formed from the continuous doped region, the doping concentration of the first well region PW2-1 formed from the discontinuous doped region PD2-1 may have lower doping concentration. Furthermore, the doping concentration of the first well region PW2-1 is adjustable by the number and size of the first doped region PD2-1. In some embodiments, as the first well region PW2-1 having tunable doping concentrations is formed without additional masks and process steps. The method of this embodiment can save manufacturing steps and costs (such as photomask costs) and improve manufacturing efficiency and manufacturing accuracy.

Next, referring to FIG. 2, multiple photolithography processes and subsequent implantation processes may be performed to form the first heavily doped region P3, the second heavily doped region P4, the third heavily doped region N3 and the fourth heavily doped region N4. The first and the second heavily doped regions P3, P4 and the first and the second heavily doped regions N1, N2 (FIG. 1) may have similar arrangements, but have opposite conductivity types. The third and fourth heavily doped regions N3, N4 and the fourth heavily doped regions P1, P2 (FIG. 1) may have similar arrangements, but have opposite conductivity types. After the aforementioned processes, the semiconductor device 500B is formed.

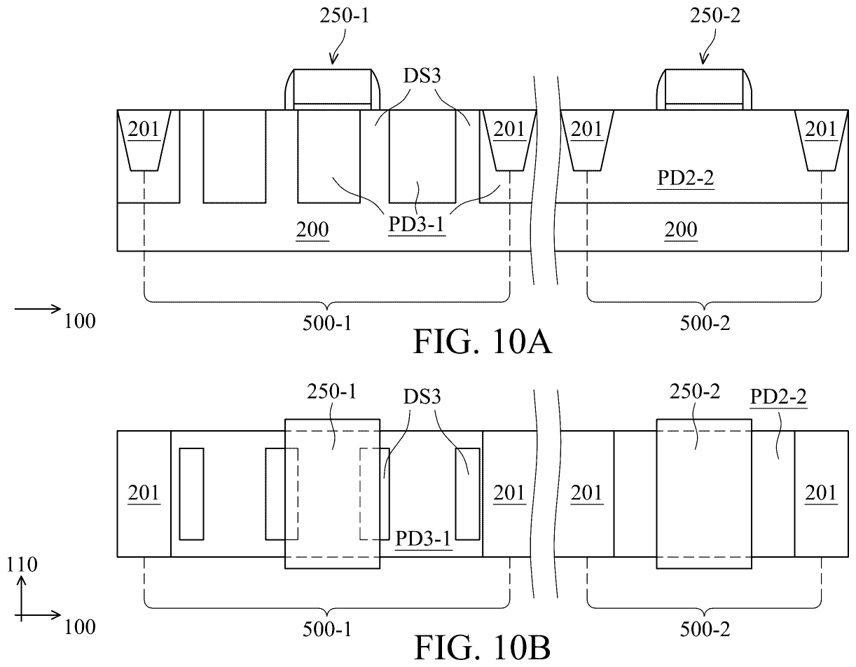

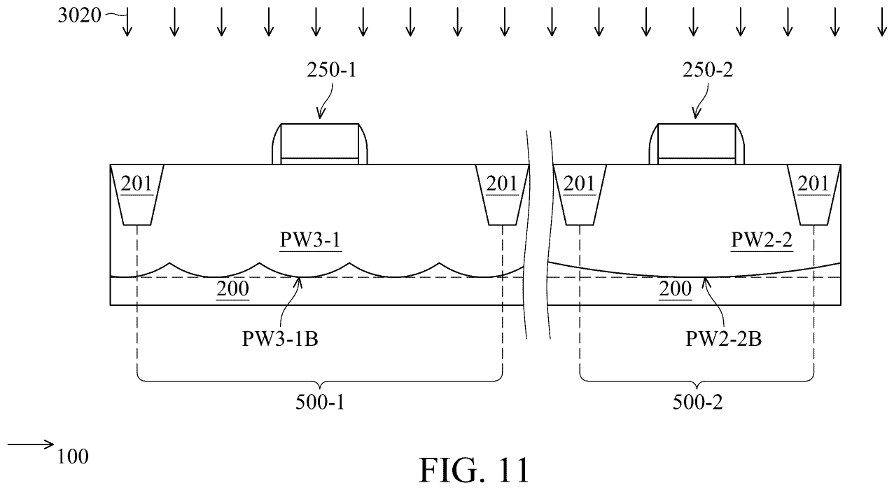

FIGS. 10A, 10B and 11 are schematic cross-sectional views at an intermediate stage of forming the semiconductor device 500C of FIG. 3 in accordance with some embodiments of the disclosure. Elements of the embodiments hereinafter, that are the same or similar as those previously described with reference to FIGS. 4A, 4B, 5A, 5B, 6, 7A, 7B, 8A, 8B and 9, are not repeated for brevity.

Referring to FIGS. 10A and 10B, an implantation process is performed to simultaneously form a first doped region PD3-1 and a third doped region PD2-2 in the whole first device region 500-1 and the whole second device region 500-2 of the semiconductor substrate 200.

In some embodiments, the first doped region PD3-1 has at least one discontinuous portion DS3 within. The discontinuous portion DS3 and the discontinuous portion DS2 (FIGS. 7A, 7B, 5A and 5B) may have similar arrangements and the same conductivity type (i.e., P-type). The third doped region PD2-2 may be formed without discontinuous portions within.

Next, still referring to FIGS. 10A and 10B, the processes similar to those shown in FIGS. 7A, 7B, 8A and 8B are performed to form the gate structures 250-1 and 250-2 on the semiconductor substrate 200 in the first device region 500-1 and the second device region 500-2. The gate structure 250-1 may overlap both the first doped region PD3-1. The gate structure 250-2 may overlap the third doped region PD2-2.

Next, referring to FIG. 11, an annealing process 3020 similar to the annealing process 2020 (FIG. 9) is performed to form a first well region PW3-1 from the first doped region PD3-1 (FIGS. 10A and 10B) and a third well region PW2-2 from the third doped region PD2-2 (FIGS. 10A and 10B). In some embodiments, the first well region PW3-1 is formed by diffusing a portion of dopants (e.g., P-type dopants) in the first doped region PD3-1 into the discontinuous portion DS3 (FIGS. 10A and 10B). Therefore, the first well region PW3-1 and the third well region PW2-2 may have different bottom profiles and doping concentrations. For example, the first well region PW3-1 may have the wavy bottom (the first bottom PW3-1B) and the third well region PW2-2 may have the arc (or rounded) bottom (e.g., the third bottom PW2-2B).

In some embodiments, the doping concentration of the first well region PW3-1 may be less than the doping concentration of the third well region PW2-2. In some embodiments, as the first well region PW3-1 in the first device region 500-1 and the third well region PW2-2 in the second device region 500-2 having different doping concentrations are simultaneously formed without additional masks and process steps.

Compared with the conventional well region formed from the continuous doped region, the doping concentration of the first well region PW3-1 formed from the discontinuous doped region PD3-1 may have lower doping concentration. Furthermore, the doping concentration of the first well region PW3-1 is adjustable by the number and size of the discontinuous portion DS3. In some embodiments, as the first well region PW3-1 having tunable doping concentrations is formed without additional masks and process steps. The method of this embodiment can save manufacturing steps and costs (such as photomask costs) and improve manufacturing efficiency and manufacturing accuracy.

Next, referring to FIG. 3, the processes similar to those shown in FIG. 2 are performed to form the first heavily doped region P5, the second heavily doped region P6, the third heavily doped region N3 and the fourth heavily doped region N4. The first heavily doped region P5 and the second heavily doped region P6 both having the first conductivity type (e.g., P-type) are located on the first well region PW3-1. The third heavily doped region N3 and the fourth heavily doped region N4 both having the second conductivity type (e.g., N-type) are located on the third well region PW2-2.

In some embodiments, the first heavily doped region P5 and the second heavily doped region P6 are arranged adjacent to the corresponding isolation features 201 in the first device region 500-1. The third heavily doped region N3 and the fourth heavily doped region N4 are arranged adjacent to the corresponding isolation features 201 in the second device region 500-2. After the aforementioned processes, the semiconductor device 500C is formed.

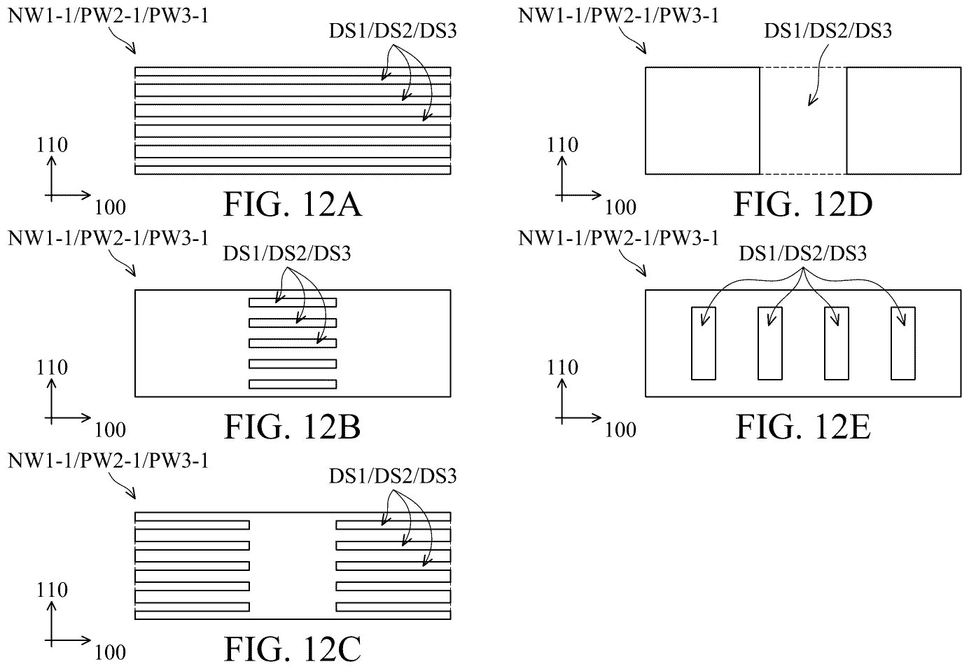

FIGS. 12A, 12B, 12C, 12D and 12E are plane views (layouts) of the first doped regions ND1-1, PD2-1 and PD3-1 for forming the first well regions NW1-1, PW2-1 and PW3-1 of FIGS. 4A, 5A, 7A, 8A and 10A, showing the arrangements of discontinuous portions DS1, DS2 and DS3 of the first doped regions NW1-1, PW2-1 and PW3-1 having a lighter doping concentration of the semiconductor device 500A, 500B and 500C of FIGS. 1-3 in accordance with some embodiments of the disclosure. The orientation of the first well regions NW1-1, PW2-1 and PW3-1 is merely an example and not limited to the disclosed embodiments.

In some embodiments, the first doped regions ND1-1, PD2-1 and PD3-1 may surround or alternately arranged with the discontinuous portions DS1, DS2 and DS3. In some embodiments, the discontinuous portions DS1, DS2 and DS3 may be separated from each other and have various shapes in the top view.

As shown in FIGS. 12A to 12C, the first doped regions ND1-1, PD2-1 and PD3-1 may have discontinuous portions DS1, DS2 and DS3 arranged periodically along the direction 110 that is different from the direction 100. In addition, the discontinuous portions DS1, DS2 and DS3 are strip-shape extending along the direction 100.

As shown in FIG. 12A, the first doped regions ND1-1, PD2-1 and PD3-1 and the discontinuous portions DS1, DS2 and DS3 may have the same length in the direction 100. Therefore, the first doped regions ND1-1, PD2-1 and PD3-1 may be divided into strip-shape sub-portions extending along the direction 100. In addition, the discontinuous portions DS1, DS2 and DS3 may have the width shorter than the width of the sub-portions of the first doped regions ND1-1, PD2-1 and PD3-1 in the direction 110. In other words, the sub-portions of the first doped regions ND1-1, PD2-1 and PD3-1 may be alternately arranged with the discontinuous portions DS1, DS2 and DS3 in the direction 110.

As shown in FIG. 12B, in the direction 100, the length of the discontinuous portions DS1, DS2 and DS3 may be shorter than that of the first doped regions ND1-1, PD2-1 and PD3-1. The discontinuous portions DS1, DS2 and DS3 may be arranged in the middle portions of the first doped regions ND1-1, PD2-1 and PD3-1. In addition, the discontinuous portions DS1, DS2 and DS3 may be surrounded by the first doped regions ND1-1, PD2-1 and PD3-1.

As shown in FIG. 12C, there are at least two discontinuous portions DS1, DS2 and DS3 are aligned each other in the direction 100 and disposed on opposite sides of the first doped regions ND1-1, PD2-1 and PD3-1. In the direction 100, the length of the discontinuous portions DS1, DS2 and DS3 may be shorter than that of the first doped regions ND1-1, PD2-1 and PD3-1.

As shown in FIGS. 12D and 12E, the first doped regions ND1-1, PD2-1 and PD3-1 may have at least one discontinuous portions DS1, DS2 and DS3. In addition, the discontinuous portions DS1, DS2 and DS3 are strip-shape extending along the direction 110.

As shown in FIG. 12D, the first doped region ND1-1/PD2-1/PD3-1 may have a single discontinuous portion DS1/DS2/DS3. The first doped regions ND1-1, PD2-1 and PD3-1 and the discontinuous portions DS1, DS2 and DS3 may have the same width in the direction 110. Therefore, the first doped regions ND1-1, PD2-1 and PD3-1 may be divided into strip-shape sub-portions extending along the direction 110. In addition, the discontinuous portions DS1, DS2 and DS3 may have the length shorter than the length of the first doped regions ND1-1, PD2-1 and PD3-1 in the direction 100. In other words, the sub-portions of the first doped regions ND1-1, PD2-1 and PD3-1 are alternately arranged with the discontinuous portions DS1, DS2 and DS3 in the direction 100.

As shown in FIG. 12E, in the direction 110, the width of the discontinuous portions DS1, DS2 and DS3 may be shorter than that of the first doped regions ND1-1, PD2-1 and PD3-1. In addition, the discontinuous portions DS1, DS2 and DS3 may be surrounded by the discontinuous portions DS1, DS2 and DS3.

Embodiments provide a semiconductor device and method for forming the same. The semiconductor device includes a semiconductor substrate, a first gate structure and a first well region. The first gate structure is disposed on the substrate. The first well region having a first conductivity type is located in the semiconductor substrate and overlapping the gate structure. In some embodiments, the first bottom of the first well region has a wave bottom surface formed without additional masks and process steps. The first well region may be formed by annealing a first doped region at least one first discontinuous portion within. A portion of first dopants in the first doped region may be diffused into the first discontinuous portion, thereby forming the first well region.

In some embodiments, the first gate structure has a first side located directly on the first well region.

In some embodiments, the semiconductor device further includes a first heavily doped region having the first conductivity type located on the first well region. In a first direction, the first side of the gate structure is separated from the first heavily doped region by a first distance, so that a portion of the first well is exposed form the gate structure and the first heavily doped region.

In some embodiments, the semiconductor device includes a first transistor disposed in a first device region. The first transistor includes the first gate structure and the first well region. The first transistor further includes a second well region having a second conductivity type located in the semiconductor substrate and adjacent to the first well region. The second well region may be formed by annealing a second doped region without discontinuous portions within. Therefore, the first bottom of the first well region and the second bottom of the second well region are connected to each other and have different profiles. For example, in a cross-sectional view, the first bottom of the first well region may have a wave profile, and the second bottom of the second well region may have an arc profile.

In some embodiments, the first transistor of semiconductor device further includes a second heavily doped region having the first conductivity type and located on the second well region. A second side of the gate structure is adjacent to the second heavily doped region.

In some embodiments, the first gate structure, the first heavily doped region and the second heavily doped region serve as the gate, the drain and the source of the first transistor, respectively.

In some embodiments, the semiconductor device further includes a second transistor disposed in a second device region. The second transistor includes a second gate structure, a second gate structure, a third heavily doped region and a fourth heavily doped region. The second gate structure is disposed on the semiconductor substrate. The third well region having the first conductivity type is located in the semiconductor substrate and overlapping the second gate structure. A third bottom of the third well region has an arc bottom surface. The third heavily doped region and the fourth heavily doped region having the second conductivity type are located on the third well region. In the first direction, the third heavily doped region and the fourth heavily doped region are adjacent to opposite sides of the second gate structure. In some embodiments, the second gate structure, the third heavily doped region and the fourth heavily doped region serve as the gate, the drain and the source of the second transistor, respectively.

When the first transistor of the semiconductor device is applied in a high voltage transistor (e.g., a HV NMOS FET or a HV PMOS FET), the performances of on resistance, breakdown voltage, drain-source capacitance and drain-bulk capacitance mainly dominated by the first well region disposed on the drain side of the first transistor. In addition, the first well region in the first device region (e.g., a HV device region) is formed simultaneously with the third well region of the second transistor (e.g., an I/O transistor including a regular NMOS FET or a regular PMOS FET) in the second device region (e.g., a regular voltage device region). In addition, the first well region is formed from the discontinuous doped region, and the third well region formed from the continuous doped region. Therefore, the first well region may have doping concentration lower than the third well region. The device performances such as on resistance, breakdown voltage, drain-source capacitance and drain-bulk capacitance of the first transistor can be modified adjusting the number and size of the discontinuous portion of the discontinuous doped region.

Compared with the conventional semiconductor device in which the HV and regular voltage well regions are formed from different continuous doped regions, the HV transistor has improved device performances while the device performance of the I/O transistor is maintained without additional masks and process steps. The method for forming the semiconductor device can save manufacturing steps and costs (such as photomask costs) and improve manufacturing efficiency and manufacturing accuracy.

When the first transistor is adopted as a HV MOS FET in the RF power amplifier for Wi-Fi network equipment, the RF power amplifier may have improved power gain, output power and reliability.

In some embodiments, the semiconductor device includes a capacitor disposed in a first device region and the second transistor disposed in the second device region. The capacitor includes the first gate structure and the first well region. The first gate structure has a second side opposite the first side and located directly on the first well region. In some embodiments, the capacitor further includes a second heavily doped region having the first conductivity type and located on the first well region. In the first direction, the second side of the gate structure is separated from the second heavily doped region by a second distance that is equal to the first distance.

In some embodiments, the first heavily doped region is electrically connected (or coupled) to the second heavily doped region. Therefore, the gate structure may serve as the first electrode of the capacitor. The first heavily doped region and the second heavily doped region may collectively serve as the second electrode of the capacitor.

When the semiconductor device includes the capacitor and the second transistor, the first well region of the capacitor in the first device region is formed simultaneously with the third well region of the second transistor (e.g., an I/O transistor including a regular NMOS FET or a regular PMOS FET) in the second device region (e.g., a regular voltage device region). The doping concentration of the first well region formed from the discontinuous doped region may have tunable doping concentration by adjusting the number and size of the discontinuous portion of the discontinuous doped region. Therefore, the capacitance of the capacitor is freely adjustable while the performance of the I/O transistor is maintained without additional masks and process steps. The method for forming the semiconductor device can save manufacturing steps and costs (such as photomask costs) and improve manufacturing efficiency and manufacturing accuracy.

While the disclosure has been described by way of example and in terms of the preferred embodiments, it should be understood that the disclosure is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor device, comprising:
a semiconductor substrate;
a gate structure disposed on the semiconductor substrate; and
a first well region having a first conductivity type located in the semiconductor substrate and overlapping the gate structure, wherein a first bottom of the first well region has a wave bottom surface.

2. The semiconductor device as claimed in claim 1, further comprising:
a second well region having a second conductivity type located in the semiconductor substrate and adjacent to the first well region, wherein the first bottom of the first well region and a second bottom of the second well region are connected to each other and have different profiles.

3. The semiconductor device as claimed in claim 2, wherein the second bottom of the second well region has an arc bottom surface.

4. The semiconductor device as claimed in claim 3, wherein the wave bottom surface of the first well region comprises a plurality of wave crests and a plurality of wave troughs, wherein the wave crests are closer to a top surface of the semiconductor substrate than the wave troughs.

5. The semiconductor device as claimed in claim 4, wherein the first well region has first sub-regions and second sub-regions alternately arranged with the first sub-regions, wherein the wave troughs are first bottom surfaces of the first sub-regions, and the wave crests are second bottom surfaces of the second sub-regions.

6. The semiconductor device as claimed in claim 5, wherein the first sub-regions have a first depth, and the second sub-regions have a second depth that is different from the first depth, wherein the first depth is measured from the bottommost point of one of the wave troughs to a top surface of the first well region, and the second depth is measured from the topmost point of one of the wave crests to the top surface of the first well region.

7. The semiconductor device as claimed in claim 6, wherein the arc bottom surface of the second well region only comprises one wave trough that protrudes in a direction away from the top surface of the semiconductor substrate.

8. The semiconductor device as claimed in claim 7, wherein a third depth measured from the bottommost point of the wave trough of the second well region to a top surface of the second well region is equal to the first depth.

9. The semiconductor device as claimed in claim 2, further comprising:
a first heavily doped region having the first conductivity type located on the first well region, wherein in a first direction, the first side of the gate structure is separated from the first heavily doped region; and
a second heavily doped region having the first conductivity type and located on the second well region,
wherein the gate structure has a first side located directly on the first well region and a second side adjacent to the second heavily doped region.

10. The semiconductor device as claimed in claim 9, wherein the gate structure, the first heavily doped region and the second heavily doped region serve as a gate, a drain and a source of a first transistor, respectively.

11. The semiconductor device as claimed in claim 1, wherein the gate structure has a first side located directly on the first well region and a second side opposite the first side and located directly on the first well region.

12. The semiconductor device as claimed in claim 11, further comprising:
a second heavily doped region having the first conductivity type and located on the first well region, wherein in the first direction, the second side of the gate structure is separated from the second heavily doped region.

13. The semiconductor device as claimed in claim 12, wherein the first heavily doped region is coupled to the second heavily doped region, and the gate structure serves as a first electrode of a capacitor, and wherein the first heavily doped region and the second heavily doped region collectively serve as a second electrode of the capacitor.

14. The semiconductor device as claimed in claim 6, further comprising:
a third well region having the first conductivity type and located in a device region of the semiconductor substrate that is different from the first well region, wherein:
a third bottom of the third well region has an arc bottom surface,
a fourth depth measured from the bottommost point of a single wave trough of the arc bottom surface of the third well region to a top surface of the third well region is equal to the first depth, and
the first well region and the third well region have different doping concentrations.

15. A semiconductor device, comprising:
a semiconductor substrate;
a gate structure disposed on the substrate; and
a first well region having a first conductivity type located in the semiconductor substrate and overlapping the gate structure, wherein the first well region has a first number of first arc bottoms, wherein the first number of first arc bottoms of the first well region is greater than or equal to 2.

16. The semiconductor device as claimed in claim 15, further comprising:
a second well region having a second conductivity type located in the semiconductor substrate and adjacent to the first well region, wherein the gate structure overlaps the second well region, wherein a second number of second arc bottoms of the second well region is equal to 1.

17. The semiconductor device as claimed in claim 15, wherein the first arc bottoms are connected to each other in turn to form a wave bottom surface of the first well region.

18. The semiconductor device as claimed in claim 16, wherein a first depth measured from the bottommost point of one of the first arc bottoms of the first well region to a top surface of the first well region is equal to a second depth measured from the bottommost point of the second arc bottom of the second well region to a top surface of the second well region.

19. The semiconductor device as claimed in claim 16, further comprising:
a first heavily doped region having the first conductivity type located on the first well region; and
a second heavily doped region having the first conductivity type and located on the second well region, wherein in a first direction, a first side of the gate structure is separated from the first heavily doped region, and a second side of the gate structure is adjacent to the second heavily doped region.

20. The semiconductor device as claimed in claim 15, wherein opposite sides of the gate structure are located directly on the first well region.
